(19) United States
(12) Patent Application Publication
(10) Pub. No.: US 2026/0282913 A1
(43) Pub. Date: Sep. 17, 2026

(54) POWER MODULE

(71) Applicants: Hyundai Motor Company, Seoul (KR); Kia Corporation, Seoul (KR)

(72) Inventors: Sung Taek HWANG, Hwaseong-si (KR); Se Yoon Jeong, Hwaseong-si (KR); Sung Won Park, Hwaseong-si (KR); Nam Sik Kong, Hwaseong-Si (KR)

(21) Appl. No.: 19/292,583

(22) Filed: Aug. 6, 2025

(30) Foreign Application Priority Data
Mar. 13, 2025 (KR) 10-2025-0032598

(51) Int. Cl. H10W 40/47; H10W 90/00; H10D 80/20; H10W 70/60; H10W 70/65; H10W 72/00

(52) U.S. Cl. CPC H10W 40/47; H10W 90/00; H10D 80/20; H10W 70/611; H10W 70/65; H10W 70/658; H10W 72/865; H10W 72/884; H10W 90/401; H10W 90/734; H10W 90/756

(57) ABSTRACT

A power module includes a substrate including an insulating layer, a first metal layer disposed on a first surface of the insulating layer, and a second metal layer disposed on a second surface of the insulating layer, and a cooling unit connected to one surface of the substrate on which the second metal layer is disposed. An external surface of the second metal layer includes at least one first cooling groove, and the cooling unit includes at least one second cooling groove forming a cooling flow path, together with the first cooling groove.

### CROSS-REFERENCE TO RELATED APPLICATION(S)

The present application claims benefit of priority to Korean Patent Application No. 10-2025-0032598 filed on March 13, 2025 in the Korean Intellectual Property Office, the disclosure of which is incorporated herein by reference in its entirety.

### TECHNICAL FIELD

The present disclosure relates to a power module.

An inverter may be used to drive motors of hybrid vehicles, electric vehicles, or the like. The inverter may convert direct current (DC) power into alternating current (AC) power, or AC power into DC power. The inverter may include a power module including a semiconductor chip performing a switching function. During the operation of the power module, heat generation of the semiconductor chip caused by high current may occur. The heat generation of the semiconductor chip may raise a temperature of the power module, and may adversely affect the driving of the power module. To ensure stable operation of the power module, it may be necessary to cool the power module by externally dissipating heat generated in the semiconductor chip.

As a method of cooling the power module, an indirect cooling method and a direct cooling method may be used. The indirect cooling method may be a method of inserting a material such as a thermal interface material (TIM) between a substrate and a cooling flow path and allowing heat to be transferred from the substrate to the cooling flow path therethrough. The direct cooling method may be a method in which the substrate and the cooling flow path are directly coupled to each other and heat transfer is performed.

### SUMMARY

An aspect of the present disclosure is to provide a power module having improved cooling performance.

Another aspect of present disclosure is to provide a power module configured for reducing substrate deformation.

According to an aspect of the present disclosure, there is disposed a power module including a substrate including an insulating layer, a first metal layer disposed on a first surface of the insulating layer, and a second metal layer disposed on a second surface of the insulating layer, and a cooling unit connected to one surface of the substrate on which the second metal layer is disposed. An external surface of the second metal layer may have at least one first cooling groove, and the cooling unit may have at least one second cooling groove forming a cooling flow path, together with the first cooling groove.

According to another aspect of the present disclosure, there is disposed a power module including a substrate including an insulating layer, a first metal layer disposed on a first surface of the insulating layer, and a second metal layer disposed on a second surface of the insulating layer, and a cooling unit connected to one surface of the substrate on which the second metal layer is disposed, the cooling unit having a cooling flow path. A. A plurality of first cooling protrusions may be disposed on an external surface of the second metal layer, and at least a portion of the cooling protrusions is disposed in the cooling flow path. A second cooling protrusion, protruding to a space between the first cooling protrusions disposed to be adjacent to each other, may be disposed on a bottom surface of the cooling unit.

Accordingly, example embodiments of the present disclosure, a power module may have improved cooling performance.

Furthermore, the power module may reduce substrate deformation.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view of a power module according to an example embodiment of the present disclosure;

FIG. 2 is an exploded view of a substrate and a cooling unit according to an example embodiment of the present disclosure;

FIG. 3 is a perspective view of a substrate according to an example embodiment of the present disclosure;

FIG. 4 is an enlarged view of portion “A” of FIG. 2;

FIG. 5 is a view of a modification of a first cooling groove and a second cooling groove according to an example embodiment of the present disclosure;

FIG. 6 is a view of another modification of a first cooling groove and a second cooling groove according to an example embodiment of the present disclosure;

FIG. 7 is a perspective view of a modification of a substrate according to an example embodiment of the present disclosure;

FIG. 8 is a cross-sectional view taken along line B-B’ of FIG. 7;

FIG. 9 is a schematic cross-sectional view of a modification of a power module according to an example embodiment of the present disclosure;

FIG. 10 is a schematic cross-sectional view of another modification of a power module according to an example embodiment of the present disclosure;

FIG. 11 is a schematic cross-sectional view of a power module according to another example embodiment of the present disclosure;

FIG. 12 is an exploded view of a substrate and a cooling unit according to another example embodiment of the present disclosure;

FIG. 13 is a perspective view of a substrate according to another example embodiment of the present disclosure;

FIG. 14 is a view of a modification of a cooling unit according to another example embodiment of the present disclosure;

FIG. 15 is a view of another modification of a cooling unit according to another example embodiment of the present disclosure;

FIG. 16 is a perspective view of a modification of a substrate according to another example embodiment of the present disclosure;

FIG. 17 is a cross-sectional view taken along line C-C’ of FIG. 16;

FIG. 18 is a schematic cross-sectional view of a modification of a power module according to another example embodiment of the present disclosure; and

FIG. 19 is a schematic cross-sectional view of another modification of a power module according to another example embodiment of the present disclosure.

### DETAILED DESCRIPTION

Various modifications may be made to the example embodiments. Here, the example embodiments are not construed as limited to the disclosure and should be understood to include all changes, equivalents, and replacements within the idea and the technical scope of the disclosure.

The terms such as first, second, A, B, (a), (b), and the like may be used herein to describe components. Each of these terminologies is not used to define an essence, order or sequence of a corresponding component but used merely to distinguish the corresponding component from other component(s). For example, a first component may be referred to a second component, and similarly the second component may also be referred to as the first component. The term “and/or” may include combinations of a plurality of related described items or any of a plurality of related described items.

The terms such as “unit,” “portion,” “part,” and the like may be used to describe various components, but the components should not be limited by the terms. The above-described terms may refer to a term indicating not only a physically/visually distinct component, but also a function or component of a corresponding portion even when not clearly divided or partitioned.

The terminology used herein is for the purpose of describing particular example embodiments only and is not to be limiting of the example embodiments. As used herein, the singular forms “a,” “an,” and “the” are intended to include the plural forms as well, unless the context clearly indicates otherwise. As used herein, the term “and/or” includes any one and any combination of any two or more of the associated listed items. It will be further understood that the terms “comprises” and/or “comprising,” when used in the present disclosure, specify the presence of stated features, integers, operations, operations, elements, components or a combination thereof, but do not preclude the presence or addition of one or more other features, integers, operations, operations, elements, components, and/or groups thereof.

Unless otherwise defined herein, all terms used herein, including technical or scientific terms, have the same meanings as those generally understood by one of ordinary skill in the art. Terms defined in dictionaries generally used should be construed to have meanings matching contextual meanings in the related art and are not to be construed as having an ideal or excessively formal meaning, unless otherwise defined herein.

In the description below, the terms “front,” “rear,” “upper,” “lower,” “top,” “bottom,” and the like used in relation to directions are defined based on the drawings.

Hereinafter, exemplary embodiments of the present disclosure will be described in more detail with reference to the accompanying drawings.

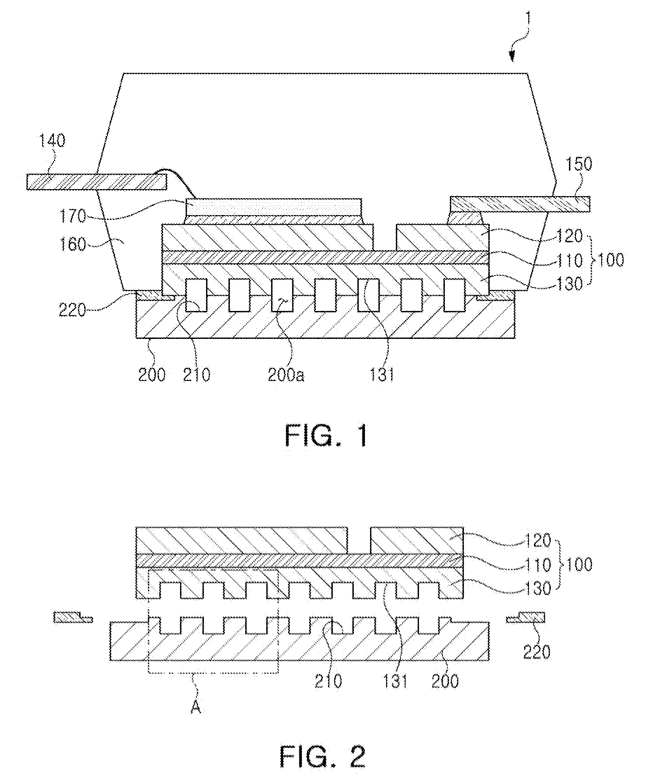

FIG. 1 is a schematic cross-sectional view of a power module according to an example embodiment of the present disclosure. Referring to FIG. 1, a power module 1 according to an example embodiment of the present disclosure may include a substrate 100 and a cooling unit 200.

The substrate 100 may include an insulating layer 110, a first metal layer 120, and a second metal layer 130. The insulating layer 110 may include at least one of ceramic or polymer resin. For example, the insulating layer 110 may include at least one of alumina, aluminum nitride, silicon nitride, epoxy, or polyimide. The insulating layer 110 may be disposed on the inside of the molded portion 160. The insulating layer 110 may include a plate shape, for example.

The first metal layer 120 may be disposed on one surface of the insulating layer 110. The first metal layer 120 may be disposed on the inside of the molded portion 160. The first metal layer 120 may include a plurality of circuit lines. The circuit line of the first metal layer 120 may refer to a circuit pattern. The circuit line of the first metal layer 120 may be connected to at least one of the power lead 140 or the signal lead 150. The first metal layer 120 may be disposed as a conductor having high electrical conductivity. For example, the first metal layer 120 may include at least one of copper, aluminum, silver, or nickel. The first metal layer 120 may be formed using lamination, deposition, or plating. A method of forming the first metal layer 120 may be replaced using various methods commonly used in the technical field to which the present disclosure pertains.

The second metal layer 130 may be disposed on the other surface of the insulating layer 110. At least a portion of the second metal layer 130 may be exposed to the outside of the molded portion 160. The cooling unit 200 may be connected to a portion of the second metal layer 120 exposed to the outside of the molded portion 160. Heat may be generated when the chip 170 mounted on the substrate 100 is operated. Heat generated in the chip 170 may be transferred to the second metal layer 130. Heat generated in the chip 170 may be externally discharged through the second metal layer 130. The second metal layer 130 may be disposed as a conductor having high thermal conductivity. For example, the second metal layer 130 may include at least one of copper or aluminum. The second metal layer 130 may be formed using lamination, deposition, or plating. A method of forming the second metal layer 130 may be replaced by various methods commonly used in the technical field to which the present disclosure pertains.

The second metal layer 130 may have at least one first cooling groove 131. The first cooling groove 131 may be disposed on an external surface of the second metal layer 130. For example, the first cooling groove 131 may be disposed on one surface of the second metal layer 130, not opposite to the insulating layer 110. The first cooling groove 131 may be disposed to be recessed inwardly from the one surface of the second metal layer 130 by a predetermined depth. When the cooling unit 200 is connected to the substrate 100, the first cooling groove 131 may be connected to a second cooling groove 210 of the cooling unit 200. The first cooling groove 131 may form a cooling flow path 200a through which a refrigerant flows, together with the second cooling groove 210 disposed in the cooling unit 200.

The cooling unit 200 may be connected to the substrate 100. For example, the cooling unit 200 may be connected to one surface of the substrate 100 on which the second metal layer 130 is disposed. A gasket 220 for ensuring watertightness may be disposed between the second metal layer 130 and the cooling unit 200.

The cooling unit 200 may be formed of a material having high thermal conductivity. For example, the cooling unit 200 may be formed of a metal material. The cooling unit 200 may externally discharge heat generated in the chip 170. Heat generated in the chip 170 may be transferred to the second metal layer 130 and the cooling unit 200 and externally discharged.

The cooling unit 200 may have at least one second cooling groove 210. The second cooling groove 210 may be disposed to be recessed inwardly from one surface of the cooling unit 200, opposite to the second metal layer 130, by a predetermined depth. The second cooling groove 210 may be connected to the first cooling groove 131 to form the cooling flow path 200a. When the cooling unit 200 is connected to the substrate 100, the first cooling groove 131 and the second cooling groove 210 may be connected to each other to form a portion of the cooling flow path 200a. For example, based on FIG. 1, the first cooling groove 131 may form an upper portion of the cooling flow path 200a, and the second cooling groove 210 may form a lower portion of the cooling flow path 200a.

The power module 1 according to an example embodiment of the present disclosure may further include a chip 170, a power lead 140, a signal lead 150, and a molded portion 160.

The chip 170 may be mounted on the substrate 100. For example, the chip 170 may be mounted on the first metal layer 120 of the substrate 100. The chip 170 may be electrically connected to the first metal layer 120. The chip 170 may, for example, include an insulated gate bipolar transistor (IGBT), a compound semiconductor (SiC), a classifier circuit, a silicon-controlled rectifier (SCR), a power transistor, a MOS transistor, a power rectifier, a power regulator, or a diode. The chip 170 may be connected to the power read 140 and the signal read 150. The chip 170 may convert power supplied through the power read 140 and output the converted power. For example, the chip 170 may receive DC power, convert the DC power into AC power, and output the AC power, and may receive AC power, convert the AC power into DC power, and output the DC power.

The power lead 140 may be disposed to supply power to the chip 170 or to output power converted by the chip 170. One end portion of the power lead 140 may be electrically connected to the chip 170 in the molded portion 160. The other end portion of the power lead 140 may be exposed to the outside of the molded portion 160.

The signal lead 150 may be disposed to input a control signal to the chip 170 or to receive state information of the chip 170. One end portion of the signal lead 150 may be electrically connected to the chip 170 in the molded portion 160. The other end portion of the signal lead 150 may be exposed to the outside of the molded portion 160.

The molded portion 160 may form an external perimeter of the power module 1. The molded portion 160 may protect the chip 170 from external moisture or impact. The molded portion 160 may improve coupling between the circuit line of the first metal layer 120, the chip 170, a power terminal 140, and a signal terminal 160. The molded portion 160 may be disposed using, for example, engineering plastic or epoxy molding compound (EMC). The molded portion 160 may be disposed to surround the substrate 100 and the chip 170. The second metal layer 130 of the substrate 100 may be exposed to the outside of the molded portion 160.

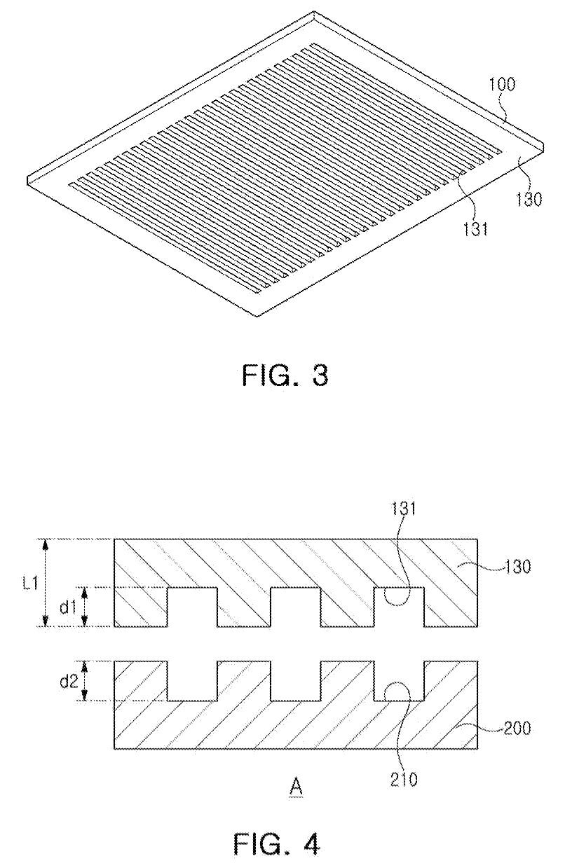

FIG. 2 is an exploded view of a substrate and a cooling unit according to an example embodiment of the present disclosure. FIG. 3 is a perspective view of a substrate according to an example embodiment of the present disclosure. FIG. 4 is an enlarged view of portion “A” of FIG. 2.

Referring to FIGS. 2 to 4, a substrate 100 may include a first cooling groove 131. The first cooling groove 131 may be disposed in a second metal layer 130 of the substrate 100. For example, the first cooling groove 131 may be disposed to be recessed inwardly from one surface of the second metal layer 130, exposed to the outside of the molded portion 160, by a predetermined depth. For example, a depth d1 of the first cooling groove 131 may be 60% or more and 80% or less of a thickness L1 of the second metal layer 130.

The first cooling groove 131 may be disposed as a plurality of first cooling grooves 131. For example, when the plurality of first cooling grooves 131 are disposed, the plurality of first cooling grooves 131 may be disposed to be parallel to each other in one direction.

A cooling unit 200 may include a second cooling groove 210. The second cooling groove 210 may be disposed on one surface of the cooling unit 200, opposite to the substrate 100. The second cooling groove 210 may be disposed to be recessed inwardly from one surface of the cooling unit 200 by a predetermined depth. For example, a sum of a depth d2 of the second cooling groove 210 and the depth d1 of the first cooling groove 131 may be 180% or more and 200% or less of a thickness of the second metal layer 130.

The cooling unit 200 may be coupled to the substrate 100. A gasket 220 for ensuring watertightness may be disposed between the cooling unit 200 and an edge portion of the substrate 100. When the cooling unit 200 is coupled to the substrate 100, the first cooling groove 131 and the second cooling groove 210 may be connected to each other to form a cooling flow path 200a through which a refrigerant flows. For example, the number of the first cooling grooves 131 and the number of the second cooling grooves 210 may be disposed to be equal to each other. When the number of the first cooling grooves 131 and the number of the second cooling grooves 210 are disposed to be equal to each other, the first cooling groove 131 may be connected to the second cooling groove 210 in a one-to-one manner to form the cooling flow path 200a. In the power module 1 according to an example embodiment of the present disclosure, the second metal layer 130 of the substrate 100 may be disposed as a portion of the cooling flow path 200a so that a distance between the chip 170 and the refrigerant and the cooling unit may be reduced, improving cooling performance of the power module 1. Furthermore, the first cooling groove 131 may be formed in the second metal layer 130 to improve a surface area in contact with the refrigerant, improving cooling performance of the power module 1. As cooling performance of the power module 1 is improved, deformation of the substrate 100, caused by heat, may be minimized.

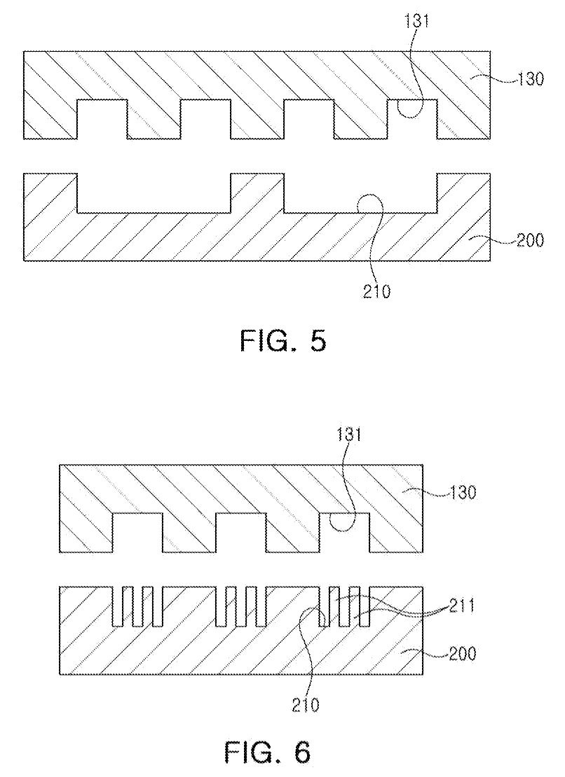

Referring to FIG. 5, as an exemplary embodiment of the present disclosure, the number of first cooling grooves 131 may be greater than the number of second cooling grooves 210. When the number of first cooling grooves 131 is greater than the number of second cooling grooves 210, the second cooling grooves 210 may be connected to at least one first cooling groove 131 to form a cooling flow path 200a. For example, one second cooling groove 210 may be connected to two first cooling grooves 131. However, the number of first cooling grooves 131 to which a plurality of second cooling grooves 210 are connected may be different. For example, the number of first cooling grooves 131 to which any one second cooling groove 210 is connected may be different from the number of first cooling grooves 131 to which the other second cooling grooves 210 are connected.

Referring to FIG. 6, in another example embodiment, the second cooling groove 210 may have at least one protrusion 211. The protrusion 211 may be disposed to protrude from a bottom surface of the second cooling groove 210. The protrusion 211 may be disposed on the inside of the cooling flow path 200a formed by the first cooling groove 131 and the second cooling groove 210. The protrusion 211 may increase a flow velocity of the refrigerant flowing in the cooling flow path 200a, improving cooling performance.

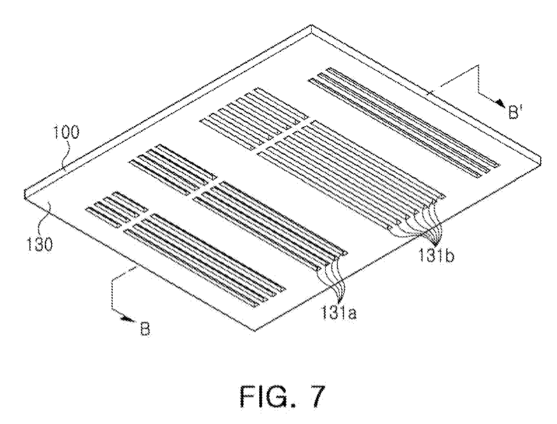

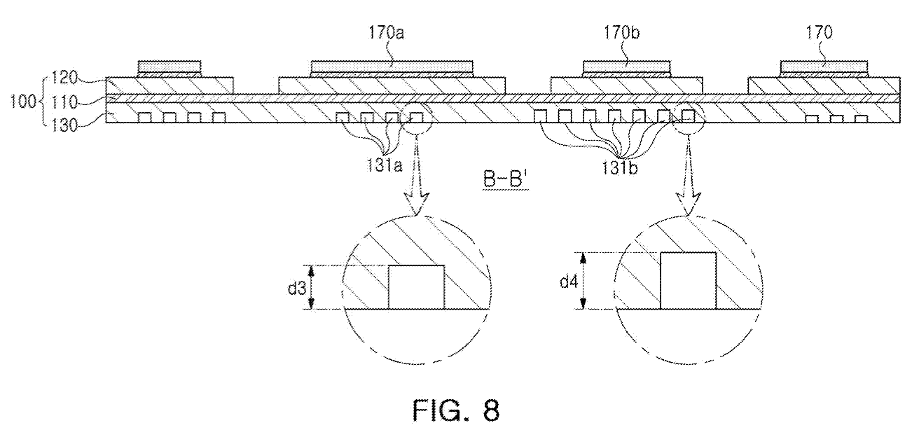

FIG. 7 is a perspective view of a modification of a substrate according to an example embodiment of the present disclosure. FIG. 8 is a cross-sectional view taken along line B-B’ of FIG. 7.

Referring to FIGS. 7 and 8, a plurality of chips 170 may be mounted on a substrate 100. A first cooling groove 131 may be disposed to oppose the chip 170. In other words, the first cooling groove 131 may be formed in a lower portion of the chip 170. A plurality of chips 170 may be disposed to oppose a plurality of first cooling grooves 131. For example, the first cooling groove 131 may include a plurality of first-first cooling grooves 131a disposed to oppose a first chip 170a, and a plurality of first-second cooling grooves 131b disposed to oppose a second chip 170b.

A width, a depth, and the number of the first cooling grooves 131 may be determined to correspond to an amount of heat generated in the chip 170. For example, at least one of a width or a depth of the first cooling groove 131, opposing one of the chips 170 having a relatively large heat generation amount, may be disposed to be greater than that of the first cooling groove 131, opposing another one of the chips 170 having a relatively small heat generation amount. Furthermore, the number of the first cooling grooves 131, opposing one of the chips 170 having a relatively large heat generation amount, may be greater than the number of the first cooling grooves 131, opposing another one of the chips 170 having a relatively small heat generation amount. Referring to the configuration illustrated FIG. 8 as an example, when a heat generation amount of the second chip 170b is greater than a heat generation amount of the first chip 170a, the number of first-second cooling grooves 131b, disposed to oppose the second chip 170b, may be greater than the number of first-first cooling grooves 131a disposed to oppose the first chip 170a. Furthermore, when the heat generation amount of the second chip 170b is greater than that of the first chip 170a, a depth d4 of the first-second cooling groove 131b, disposed to oppose the second chip 170b, may be greater than a depth d3 of the first-first cooling groove 131a disposed to oppose the first chip 170a.

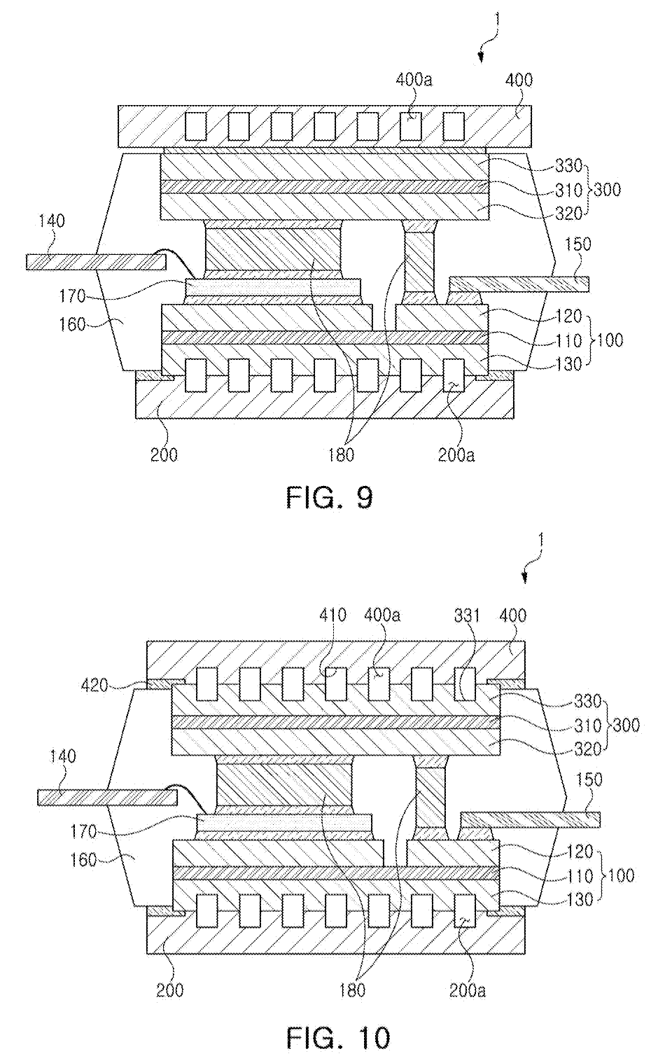

FIG. 9 is a schematic cross-sectional view of a modification of a power module according to an example embodiment of the present disclosure. FIG. 10 is a schematic cross-sectional view of another modification of a power module according to an example embodiment of the present disclosure.

Referring to FIG. 9, a power module 1 may include a lower substrate 100, a lower cooling unit 200, an upper substrate 300, and an upper cooling unit 400. In the example embodiment illustrated in FIG. 9, the power module 1 may correspond to a double-sided cooling type power module. Here, configurations of the lower substrate 100, the lower cooling unit 200, a chip 170, a power lead 140, a signal lead 150, and a molded portion 160 may be substantially the same as those of the substrate 100, the cooling unit 200, the chip 170, the power lead 140, the signal lead 150, and the molded portion 160 illustrated in FIG. 1. Accordingly, detailed descriptions of the same configurations are omitted and replaced with the above descriptions.

The upper substrate 300 may be disposed on an upper portion of the lower substrate 100. The upper substrate 300 may include an upper insulating layer 310, an upper internal metal layer 320, and an upper external metal layer 330. The upper insulating layer 310 may include at least one of ceramic or polymer resin. For example, the upper insulating layer 310 may include at least one of alumina, aluminum nitride, silicon nitride, epoxy, or polyimide. The upper insulating layer 310 may be disposed on the inside of the molded portion 160.

An upper internal metal layer 320 may be disposed on one surface of the upper insulating layer 310. The upper internal metal layer 320 may be disposed on the inside of the molded portion 160. The upper internal metal layer 320 may include a plurality of circuit lines. The circuit line of the upper internal metal layer 320 may be a circuit pattern.

The upper external metal layer 330 may be disposed on the other surface of the upper insulating layer 310. At least a portion of the upper external metal layer 330 may be exposed to the outside of the molded portion 160. The upper cooling unit 400 may be connected to a portion of the upper external metal layer 330 exposed to the outside of the molded portion 160. The upper cooling unit 400 may include at least one upper cooling flow path 400a.

The upper substrate 300 may be connected to the lower substrate 100 through a spacer 180. One end portion of the spacer 180 may be connected to the upper internal metal layer 320 of the upper substrate 300, and the other end portion of the spacer 180 may be connected to the chip 170 or a first metal layer 120. The spacer 180 may electrically connect the upper substrate 300 and the chip 170 to each other, and may electrically connect the upper substrate 300 and the first metal layer 120 to each other.

Referring to FIG. 10, a power module 1 may include a lower substrate 100, a lower cooling unit 200, an upper substrate 300, and an upper cooling unit 400. Except for configurations of an upper external metal layer 330 of the upper substrate 300 and the upper cooling unit 400, other configurations may be the same as those illustrated in FIG. 9. Accordingly, detailed descriptions of the same configurations are omitted and replaced with the above descriptions.

The upper substrate 300 and the lower substrate 100 may have the same shape. For example, the upper external metal layer 330 may have at least one upper first cooling groove 331. The upper first cooling groove 331 may be disposed on an external surface of the upper external metal layer 330. For example, the upper first cooling groove 331 may be disposed on one surface of the upper external metal layer 330, not opposite to the upper insulating layer 310. The upper first cooling groove 331 may be disposed to be recessed inwardly from one surface of the upper external metal layer 330 by a predetermined depth. When the upper cooling unit 400 is connected to the upper substrate 300, the upper first cooling groove 331 may be connected to an upper second cooling groove 410 of the upper cooling unit 400. The upper first cooling groove 331 may form the upper cooling flow path 400a through which a refrigerant flows, together with the upper second cooling groove 410 disposed in the upper cooling unit 400.

The upper cooling unit 400 may be connected to the upper substrate 300. For example, the upper cooling unit 400 may be connected to one surface of the upper substrate 300 on which the upper external metal layer 330 is disposed. A gasket 420 for ensuring watertightness may be disposed between the upper external metal layer 330 and the upper cooling unit 400. The upper cooling unit 400 may have at least one upper second cooling groove 410. The upper second cooling groove 410 may be disposed to be recessed inwardly from one surface of the upper cooling unit 400, opposite to the upper external metal layer 330, by a predetermined depth. The upper second cooling groove 410 may be connected to the upper first cooling groove 331 to form the upper cooling flow path 400a. When the upper cooling unit 400 is connected to the upper substrate 300, the upper first cooling groove 331 and the upper second cooling groove 410 may be connected to each other to form a portion of the upper cooling flow path 400a, respectively. For example, based on FIG. 10, the upper first cooling groove 331 may form a lower portion of the upper cooling flow path 400a, and the upper second cooling groove 410 may form an upper portion of the upper cooling flow path 400a.

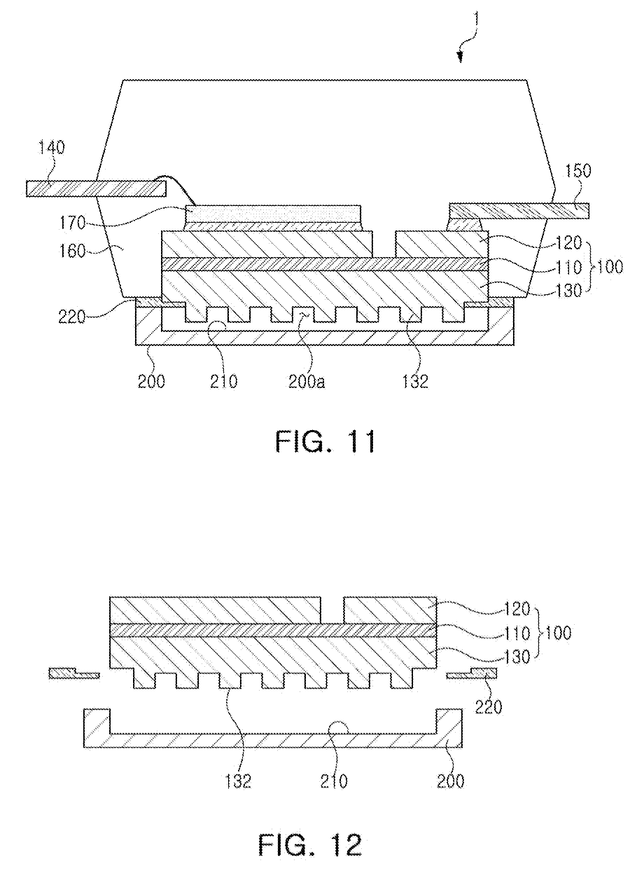

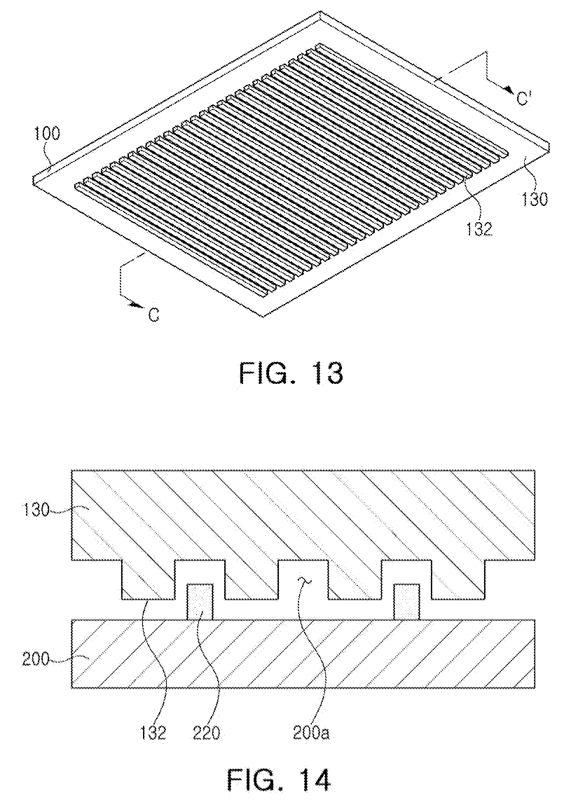

FIG. 11 is a schematic cross-sectional view of a power module according to another example embodiment of the present disclosure. FIG. 12 is an exploded view of a substrate and a cooling unit according to another example embodiment of the present disclosure. FIG. 13 is a perspective view of a substrate according to another example embodiment of the present disclosure.

Referring to FIGS. 11 to 13, a power module 1 may include a substrate 100 and a cooling unit 200. Except for detailed configurations of a second metal layer 130 of the substrate 100 and the cooling unit 200, other configurations may be substantially the same as those of the power module illustrated in FIG. 1. Accordingly, detailed descriptions of the same configurations are omitted and replaced with the above descriptions.

The substrate 100 may include an insulating layer 110, a first metal layer 120, and a second metal layer 130. A plurality of first cooling protrusions 132 may be disposed on an external surface of the second metal layer 130. The first cooling protrusion 132 may be disposed to protrude from one surface of the second metal layer 130, exposed to the outside of a molded portion 160, by a predetermined height. When the cooling unit 200 is connected to the substrate 100, at least a portion of the first cooling protrusion 132 may be disposed in a cooling flow path 200a of the cooling unit 200.

The cooling unit 200 may be connected to the substrate 100. The cooling unit 200 may be connected to one surface of the substrate 100 on which the second metal layer 130 is disposed. A gasket 220 for ensuring watertightness may be disposed between the second metal layer 130 and the cooling unit 200. Heat generated in the chip 170 may be transferred to the second metal layer 130 and the cooling unit 200 and externally discharged.

The cooling unit 200 may include a cooling groove 210. The cooling groove 210 may be disposed to be recessed inwardly from one surface of the cooling unit 200, opposite to the second metal layer 130, by a predetermined depth. When the cooling unit 200 is connected to the substrate 100, the cooling groove 210 may form the cooling flow path 200a, together with the substrate 100. In the instant case, at least a portion of the first cooling protrusion 132 may be disposed in the cooling flow path 200a.

The power module 1 may further include a chip 170, a power lead 140, a signal lead 150, and a molded portion 160.

The power module 1 according to another example embodiment of the present disclosure may allow the second metal layer 130 of the substrate 130 to be in direct contact with a refrigerant, improving cooling performance. As cooling performance of the power module 1 is improved, deformation of the substrate 100, caused by heat, may be minimized.

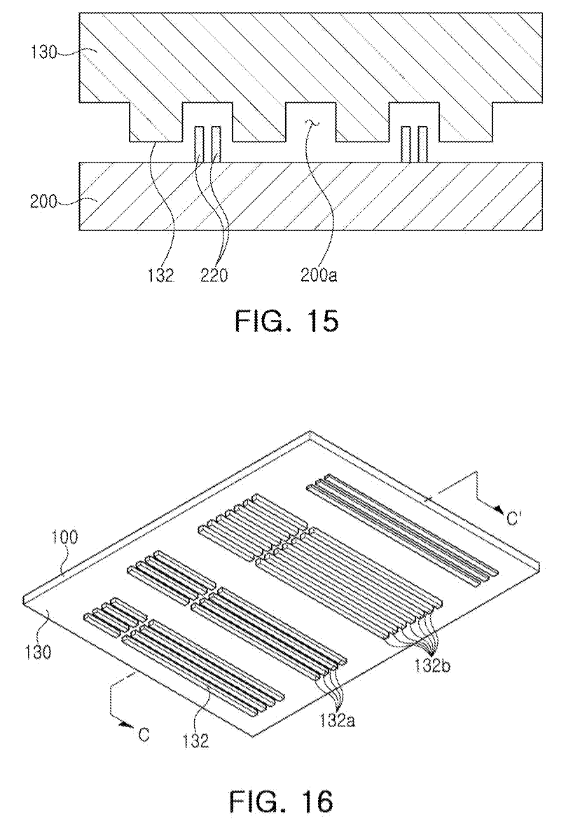

FIGS. 14 and 15 are views of a modification of a cooling unit according to another example embodiment of the present disclosure. Referring to FIG. 14, a cooling unit 200 may include at least one second cooling protrusion 220. The second cooling protrusion 220 may be disposed to protrude from a bottom surface of the cooling unit 200, for example. The second cooling protrusion 220 may protrude to a space between first cooling protrusions 132 disposed to be adjacent to each other. At least a portion of the second cooling protrusion 220 may be disposed between the first cooling protrusions 132 disposed to be adjacent to each other. A plurality of second cooling protrusions 220 may be disposed (see FIG. 15). The second cooling protrusions 220 may be integrally disposed in the cooling unit 200. Alternatively, the second cooling protrusion 220 may be manufactured as a separate component and then coupled to the bottom surface of the cooling unit 200. For example, the second cooling protrusion 220 may be separately manufactured and then coupled to the bottom surface of the cooling unit 200 using at least one method selected from welding, adhesion, screw fastening, or press-fitting. The second cooling protrusion 220 may increase a flow velocity of a refrigerant flowing in a cooling flow path 200a, improving cooling efficiency of the power module 1.

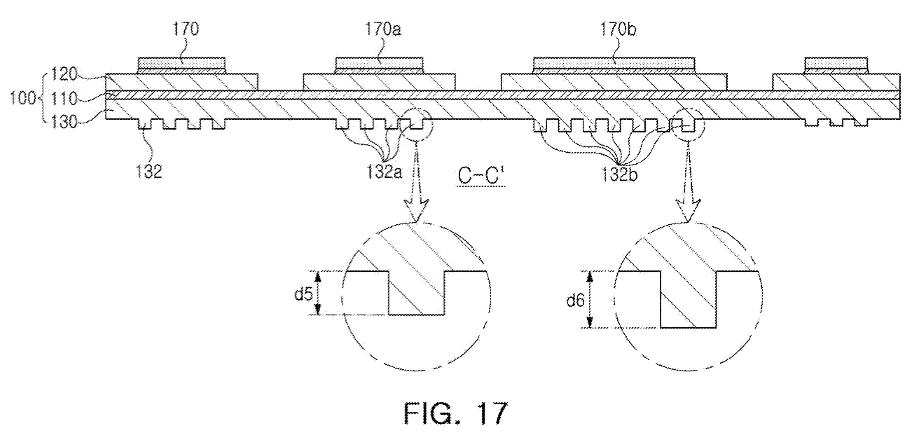

FIG. 16 is a perspective view of a modification of a substrate according to another example embodiment of the present disclosure. FIG. 17 is a cross-sectional view taken along line C-C’ of FIG. 16.

Referring to FIGS. 16 and 17, a plurality of chips 170 may be mounted on a substrate 100. A first cooling protrusion 132 may be disposed to oppose the chip 170. In other words, the first cooling protrusion 132 may be formed on a lower portion of the chip 170. The plurality of chips 170 may be disposed to oppose a plurality of first cooling protrusions 132, respectively. For example, the first cooling protrusion 132 may include a plurality of first-first cooling protrusions 132a disposed to oppose a first chip 170a, and a plurality of first-second cooling protrusions 132b disposed to oppose a second chip 170b.

A width, a height, and the number of the first cooling protrusions 132 may be determined to correspond to an amount of heat generated in the chip 170. For example, at least one of a width or a height of the first cooling protrusion 132, opposing one of the chips 170 having a relatively large heat generation amount, may be disposed to be greater than that of the first cooling protrusion 132, opposing another one of the chips 170 having a relatively small heat generation amount. Alternatively, the number of the first cooling protrusions 132, opposing one of the chips 170 having a relatively large heat generation amount, may be greater than the number of the first cooling protrusions 132, opposing another one of the chips 170 having a relatively small heat generation amount. Referring to the configuration illustrated in FIG. 17 as an example, when an amount of heat generated in the second chip 170b is greater than an amount of heat generated in the first chip 170a, the number of the first-second cooling protrusions 132b, disposed to oppose the second chip 170b, may be greater than the number of the first-first cooling protrusions 132a, disposed to oppose the first chip 170a. Furthermore, when the amount of heat generated in the second chip 170b is greater than the amount of heat generated in the first chip 170a, a height d6 of the first-second cooling protrusion 132b, disposed to oppose the second chip 170b, may be greater than a height d5 of the first-first cooling protrusion 132a, disposed to oppose the first chip 170a.

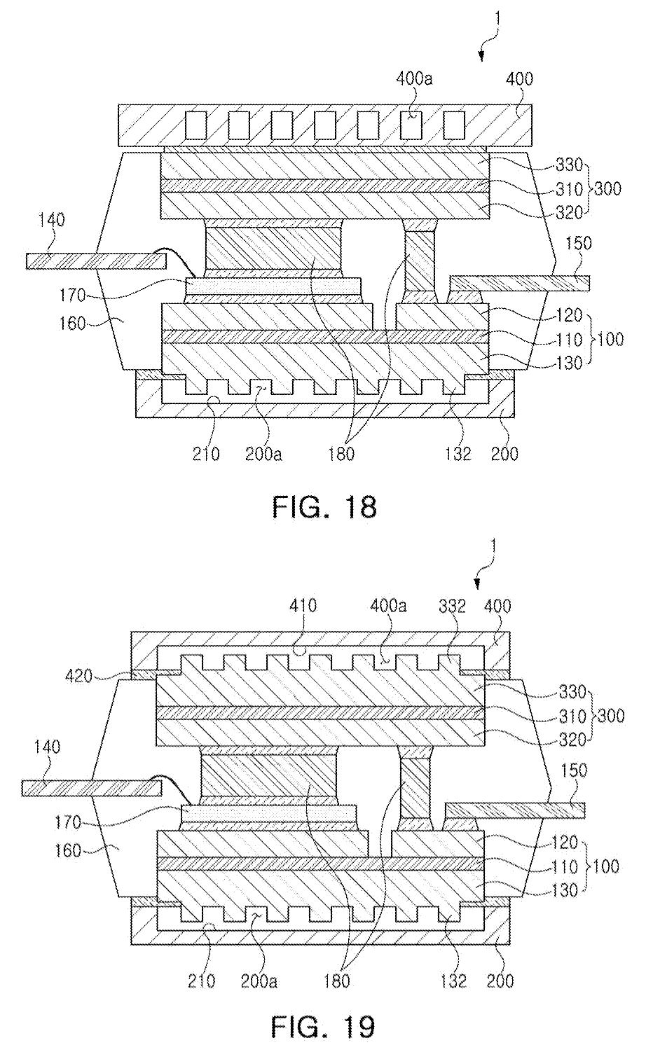

FIG. 18 is a schematic cross-sectional view of a modification of a power module according to another example embodiment of the present disclosure. FIG. 19 is a schematic cross-sectional view of another modification of a power module according to another example embodiment of the present disclosure.

Referring to FIG. 18, a power module 1 may include a lower substrate 100, a lower cooling unit 200, an upper substrate 300, and an upper cooling unit 400. In the example embodiment illustrated in FIG. 18, the power module 1 may correspond to a double-sided cooling type power module. Here, configurations of the lower substrate 100, the lower cooling unit 200, a chip 170, a power lead 140, a signal lead 150, and a molded portion 160 may be substantially the same as those of the substrate 100, the cooling unit 200, the chip 140, the power lead 140, the signal lead 150, and the molded portion 160 illustrated in FIG. 11. Accordingly, detailed descriptions of the same configurations are omitted and replaced with the above descriptions.

The upper substrate 300 may be disposed on an upper portion of the lower substrate 100. The upper substrate 300 may include an upper insulating layer 310, an upper internal metal layer 320, and an upper external metal layer 330. The upper insulating layer 310 may include at least one of ceramic or polymer resin. For example, the upper insulating layer 310 may include at least one of alumina, aluminum nitride, silicon nitride, epoxy, or polyimide. The upper insulating layer 310 may be disposed on the inside of the molded portion 160.

The upper internal metal layer 320 may be disposed on one surface of the upper insulating layer 310. The upper internal metal layer 320 may be disposed on the inside of the molded portion 160. The upper internal metal layer 320 may include a plurality of circuit lines. The circuit line of the upper internal metal layer 320 may be a circuit pattern.

The upper external metal layer 330 may be disposed on the other surface of the upper insulating layer 310. At least a portion of the upper external metal layer 330 may be exposed to the outside of the molded portion 160. The upper cooling unit 400 may be connected to a portion of the upper external metal layer 330 exposed to the outside of the molded portion 160. The upper cooling unit 400 may include at least one upper cooling flow path 400a.

The upper substrate 300 may be connected to the lower substrate 100 through a spacer 180. One end portion of the spacer 180 may be connected to the upper internal metal layer 320 of the upper substrate 300, and the other end portion of the spacer 180 may be connected to the chip 170 or the first metal layer 120. The spacer 180 may electrically connect the upper substrate 300 and the chip 170 to each other, and may electrically connect the upper substrate 300 and the first metal layer 120 to each other.

Referring to FIG. 19, a power module 1 may include a lower substrate 100, a lower cooling unit 200, an upper substrate 300, and an upper cooling unit 400. In the example embodiment illustrated in FIG. 19, except for configurations of an upper external metal layer 330 of the upper substrate 300 and the upper cooling unit 400, other configurations may be substantially the same as those illustrated in FIG. 18. Accordingly, detailed descriptions of the same configurations are omitted and replaced with the above descriptions.

The upper substrate 300 and the lower substrate 100 may have the same shape. For example, the upper external metal layer 330 may have at least one upper first cooling protrusion 332. The upper first cooling protrusion 332 may be disposed to protrude from an external surface of the upper external metal layer 330. For example, the upper first cooling protrusion 33 may be disposed to protrude from one surface of the upper external metal layer 330, not opposite to the upper insulating layer 310. When the upper cooling unit 400 is connected to the upper substrate 300, at least a portion of the upper first cooling protrusion 332 may be disposed in an upper cooling flow path 400a of the upper cooling unit 400.

The upper cooling unit 400 may be connected to the upper substrate 300. The upper cooling unit 400 may be connected to one surface of the upper substrate 300 on which the upper external metal layer 330 is disposed. An upper gasket 420 for watertightness may be disposed between the upper external metal layer 330 and the upper cooling unit 400.

The upper cooling unit 400 may include an upper cooling groove 410. The upper cooling groove 410 may be disposed to be recessed inwardly from one surface of the upper cooling unit 400, opposite to the upper external metal layer 330, by a predetermined depth. When the upper cooling unit 400 is connected to the upper substrate 300, the upper cooling groove 410 may form an upper cooling flow path 400a, together with the substrate 100. In the instant case, at least a portion of the upper first cooling protrusion 332 may be disposed in the upper cooling flow path 400a.

All example embodiments of the above-described power module may be combined and implemented with each other, disposed that configurations included in the example embodiments do not correspond to configurations that are inconsistent with one another.

While example embodiments have been shown and described above, it will be apparent to those skilled in the art that modifications and variations could be made without departing from the scope of the present disclosure as defined by the appended claims.

What is claimed is:

1. A power module comprising:
a substrate including an insulating layer, a first metal layer disposed on a first surface of the insulating layer, and a second metal layer disposed on a second surface of the insulating layer; and
a cooling unit connected to one surface of the substrate on which the second metal layer is disposed;
wherein an external surface of the second metal layer includes at least one first cooling groove, and the cooling unit includes at least one second cooling groove forming a cooling flow path, together with the first cooling groove.

2. The power module of claim 1, wherein a bottom surface of the at least one second cooling groove includes at least one protrusion protruding therefrom.

3. The power module of claim 1,
wherein a number of first cooling grooves and a number of second cooling grooves are equal to each other, and
wherein the first cooling grooves are connected to the second cooling grooves in a one-to-one manner to form the cooling flow path.

4. The power module of claim 1,
wherein a number of first cooling grooves is greater than a number of second cooling grooves, and
wherein a second cooling groove is connected to the first cooling grooves to form the cooling flow path.

5. The power module of claim 1, wherein a depth of the at least one first cooling groove is 60% or more and 80% or less of a thickness of the second metal layer.

6. The power module of claim 1, wherein a sum of a depth of the at least one first cooling groove and a depth of the at least one second cooling groove is 180% or more and 200% or less of a thickness of the second metal layer.

7. The power module of claim 1, wherein the at least one first cooling groove is disposed to be recessed inwardly from one surface of the second metal layer, not opposite to the insulating layer.

8. The power module of claim 1,
wherein a plurality of chips are mounted on the substrate, and
wherein the first cooling groove is disposed to oppose the chip.

9. The power module of claim 8, wherein the plurality of chips are disposed to oppose a plurality of first cooling grooves, respectively.

10. The power module of claim 8, wherein at least one of a width or depth of the first cooling groove, opposing one of the chips having a relatively large heat generation amount, is greater than that of the first cooling groove, opposing another one of the chips having a relatively small heat generation amount.

11. The power module of claim 8, wherein a number of first cooling grooves, opposing one of the chips having a relatively large heat generation amount, is greater than a number of first cooling grooves, opposing another one of the chips having a relatively small heat generation amount.

12. The power module of claim 1, wherein a gasket is disposed between the second metal layer and the cooling unit.

13. A power module comprising:
a substrate including an insulating layer, a first metal layer disposed on a first surface of the insulating layer, and a second metal layer disposed on a second surface of the insulating layer; and
a cooling unit connected to one surface of the substrate on which the second metal layer is disposed, the cooling unit having a cooling flow path;
wherein a plurality of first cooling protrusions are disposed on an external surface of the second metal layer, and at least a portion of the first cooling protrusions is disposed in the cooling flow path, and
wherein a second cooling protrusion, protruding to a space between the first cooling protrusions disposed to be adjacent to each other, is disposed on a bottom surface of the cooling unit.

14. The power module of claim 13, wherein the second cooling protrusion is formed integrally with the cooling unit.

15. The power module of claim 13, wherein the second cooling protrusion is coupled to the bottom surface of the cooling unit using at least one method selected from welding, adhesion, screw fastening, or press-fitting.

16. The power module of claim 13,
wherein a plurality of chips are mounted on the first metal layer, and
wherein the first cooling protrusion is disposed to oppose the chip.

17. The power module of claim 16, wherein the plurality of chips are disposed to oppose the plurality of first cooling protrusions, respectively.

18. The power module of claim 16, wherein at least one of a width or height of the first cooling protrusion, opposing one of the chips having a relatively large heat generation amount, is greater than that of the first cooling protrusion, opposing another one of the chips having a relatively small heat generation amount.

19. The power module of claim 16, wherein a number of the first cooling protrusions, opposing one of the chips having a relatively large heat generation amount, is greater than a number of the first cooling protrusions, opposing another one of the chips having a relatively small heat generation amount.

20. The power module of claim 13, wherein a gasket is disposed between the second metal layer and the cooling unit.
